(19) United States
(12) Patent Application Publication
(10) Pub. No.: US 2025/0039805 A1
(43) Pub. Date: Jan. 30, 2025

(54) Electronic Device with Antenna Array Tapering

(71) Applicant: Apple Inc., Cupertino, CA (US)

(72) Inventors: Franz J Eder, Neubiberg (DE); Carlo Tosetti, Munich (DE); Josef Hagn, Taufkirchen (DE); Andre Janssen, Munich (DE); Abbas Komijani, Mountain View, CA (US); Iliah Konstantinovsky, Tel Aviv (IL); Roman Rainov, Hod HaSharon (IL); Amit Freiman, San Jose, CA (US); Amitoj Singh, Sunnyvale, CA (US); Bernhard Sogl, Unterhaching (DE)

(21) Appl. No.: 18/358,516

(22) Filed: Jul. 25, 2023

(51) Int. Cl. H04W 52/24; G01R 29/08; H01Q 3/26; H04B 7/08; H04B 17/21; H04W 24/08

(52) U.S. Cl. CPC H04W 52/246; G01R 29/0871; H01Q 3/2652; H04B 7/0874; H04B 17/221; H04W 24/08

(57) ABSTRACT

A user equipment (UE) device may communicate with a wireless base station (BS). Each antenna in a phased antenna array on the UE may receive a reference signal transmitted by the BS during the beam training interval. Transceiver circuitry may measure wireless performance metric data from the reference signal. While receiving the reference signal, control circuitry may selectively activate different individual antennas, may selectively activate different subsets of antennas, or may concurrently activate all of the antennas in the array. The control circuitry may identify, based on the wireless performance metric data, a first set of the antennas in the array to that are being blocked by an external object and a second set of antennas array that are not blocked. After the beam training interval, the transceiver may use the second set of antennas to convey wireless data with the BS while the first set of antennas are disabled.

### FIELD

This disclosure relates generally to electronic devices and, more particularly, to electronic devices with wireless circuitry.

### BACKGROUND

Electronic devices are often provided with wireless capabilities. An electronic device with wireless capabilities has wireless circuitry that includes one or more antennas. The wireless circuitry is used to perform communications using radio-frequency signals conveyed by the antennas.

As software applications on electronic devices become more data-intensive over time, demand has grown for electronic devices that support wireless communications at higher data rates. However, the maximum data rate supported by electronic devices is limited by the frequency of the radio-frequency signals. As the frequency of the radio-frequency signals increases, it can become increasingly difficult to perform satisfactory wireless communications because the signals become subject to significant over-the-air attenuation. In addition, if care is not taken, external objects in the vicinity of the antennas can limit radio-frequency performance in conveying the signals.

### SUMMARY

A user equipment (UE) device may communicate with a wireless base station (BS). The BS may transmit a reference signal to the UE device during a beam training interval. The UE device may have antennas arranged in a phased antenna array. Each antenna in the phased antenna array may receive the reference signal during the beam training interval. Transceiver circuitry coupled to the phased antenna array may measure wireless performance metric data from the reference signal received by the phased antenna array. While receiving the reference signal, control circuitry on the UE device may selectively activate different individual antennas in the phased antenna array at different times, may selectively activate different subsets of antennas in the phased antenna array at different times, or may concurrently activate all of the antennas in the phased antenna array while adjusting phase settings across the phased antenna array.

The control circuitry may identify, based on the wireless performance metric data, a first set of the antennas in the phased antenna array to disable during subsequent communications and a second set of antennas in the phased antenna array to keep active during subsequent communications. The first set of antennas may, for example, be covered by an external object. After the beam training interval, the transceiver circuitry may use the second set of antennas to convey wireless data with the BS while the first set of antennas are disabled. This may serve to optimize wireless performance of the phased antenna array in the presence of the external object and may help to minimize power consumption on the UE device, even as the external object and/or the UE device move over time.

An aspect of the disclosure provides a method of operating an electronic device having antennas arranged in a phased antenna array. The method can include receiving, using the phased antenna array, radio-frequency signals transmitted by an external device. The method can include measuring, using transceiver circuitry communicably coupled to the phased antenna array, wireless performance metric data from the radio-frequency signals received by the phased antenna array. The method can include disabling, using one or more processors, a first set of antennas in the phased antenna array, the antennas in the first set being selected based on the wireless performance metric data. The method can include conveying, using a second set of antennas in the phased antenna array, wireless data while the first set of antennas is disabled.

An aspect of the disclosure provides an electronic device. The electronic device can include antennas arranged in a phased antenna array, the phased antenna array being configured to receive a reference signal transmitted by an external device. The electronic device can include signal paths coupled to the antennas in the phased antenna array. The electronic device can include transceiver circuitry communicably coupled to the antennas in the phased antenna array over the signal paths. The electronic device can include one or more processors configured to deactivate a first subset of the signal paths based on the reference signal received by the phased antenna array, the transceiver circuitry being configured to transmit wireless data to the phased antenna array over a second subset of the signal paths while the first subset of the signal paths is deactivated.

An aspect of the disclosure provides a method of operating a user equipment (UE) device to communicate with a wireless base station. The method can include receiving, using a phased antenna array, a reference signal transmitted by the wireless base station. The method can include measuring, using transceiver circuitry, wireless performance metric data from the reference signal received by the phased antenna array. The method can include detecting, using one or more processors and based on the wireless performance metric data, a first set of antennas in the phased antenna array that are at least partially overlapping an external object. The method can include conveying, using a second set of antennas in the phased antenna array that is different from the first set of antennas, wireless data while the first set of antennas is inactive.

### BRIEF DESCRIPTION OF THE DRAWINGS

FIG. 1 is a schematic block diagram of an illustrative communications system that includes a user equipment device that wirelessly communicates with a wireless base station in accordance with some embodiments.

FIG. 2 is a diagram showing how an illustrative user equipment device may sweep a phased antenna array over different signal beams during a beam training interval with a wireless base station in accordance with some embodiments.

FIG. 3 is a circuit diagram of an illustrative phased antenna array that may perform array tapering based on radio-frequency signals received by the phased antenna array in accordance with some embodiments.

FIG. 4 is a flow chart of illustrative operations involved in using a user equipment device to perform array tapering in communicating with a wireless base station in accordance with some embodiments.

FIG. 5 is a flow chart of illustrative operations that may be performed by a user equipment device to detect antennas to disable for communicating with a wireless base station based on radio-frequency measurements performed by sweeping through single active antennas in a phased antenna array in accordance with some embodiments.

FIG. 6 is a flow chart of illustrative operations that may be performed by a user equipment device to detect antennas to disable for communicating with a wireless base station based on radio-frequency measurements performed by sweeping through subsets of active antennas in a phased antenna array in accordance with some embodiments.

FIG. 7 is a flow chart of illustrative operations that may be performed by a user equipment device to detect antennas to disable for communicating with a wireless base station based on radio-frequency measurements performed concurrently by all antennas in a phased antenna array in accordance with some embodiments.

FIG. 8 is a plot showing how performing array tapering in communicating with a wireless base station may optimize wireless performance of a user equipment device in accordance with some embodiments.

### DETAILED DESCRIPTION

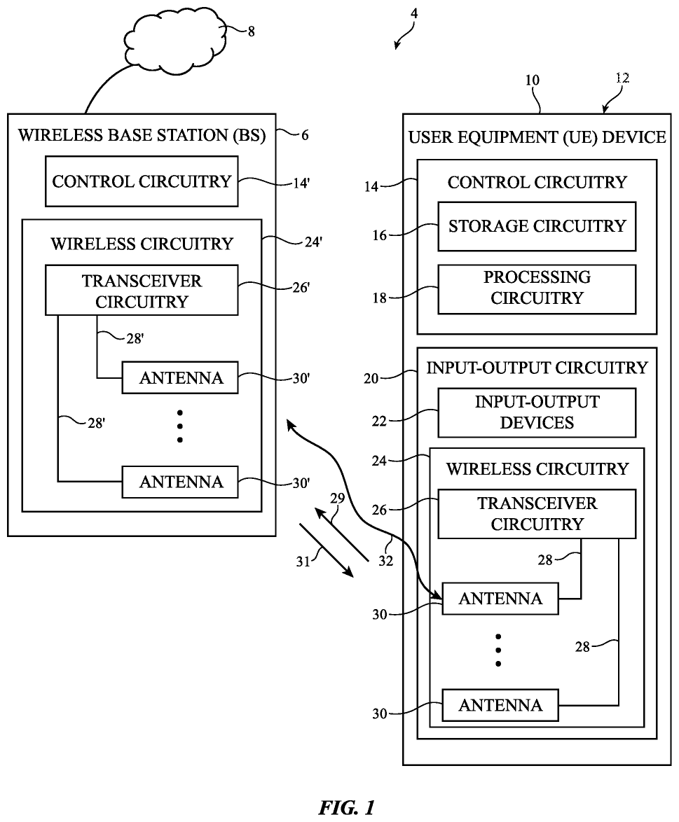

FIG. 1 is a schematic diagram of an illustrative communications system 4 (sometimes referred to herein as communications network 4) for conveying wireless data between communications terminals. Communications system 4 may include network nodes (e.g., communications terminals). The network nodes may include user equipment (UE) such as one or more UE devices 10. The network nodes may also include external communications equipment (e.g., communications equipment other than UE devices 10) such as external communications equipment 6. External communications equipment 6 may include one or more electronic devices and may be a wireless base station, wireless access point, or other wireless equipment for example. Implementations in which external communications equipment 6 is a wireless base station (e.g., of a cellular telephone network) are described herein as an example. External communications equipment 6 may therefore sometimes be referred to herein as wireless base station 6 or simply as base station (BS) 6. UE device 10 and BS 6 may communicate with each other using one or more wireless communications links. If desired, UE device 10 may wirelessly communicate with BS 6 without passing communications through any other intervening network nodes in communications system 4 (e.g., UE device 10 may communicate directly with BS 6 over-the-air).

BS 6 may be communicably coupled to a larger communications network 8 via wired and/or wireless links. The larger communications network may include one or more wired communications links (e.g., communications links formed using cabling such as ethernet cables, radio-frequency cables such as coaxial cables or other transmission lines, optical fibers or other optical cables, etc.), one or more wireless communications links (e.g., short range wireless communications links that operate over a range of inches, feet, or tens of feet, medium range wireless communications links that operate over a range of hundreds of feet, thousands of feet, miles, or tens of miles, and/or long range wireless communications links that operate over a range of hundreds or thousands of miles, etc.), communications gateways, wireless access points, base stations, switches, routers, servers, modems, repeaters, telephone lines, network cards, line cards, portals, user equipment (e.g., computing devices, mobile devices, etc.), etc. The larger communications network may include communications (network) nodes or terminals coupled together using these components or other components (e.g., some or all of a mesh network, relay network, ring network, local area network, wireless local area network, personal area network, cloud network, star network, tree network, or networks of communications nodes having other network topologies), the Internet, combinations of these, etc. UE device 10 may send data to and/or may receive data from other nodes or terminals in the larger communications network via BS 6 (e.g., BS 6 may serve as an interface between UE device 10 and the rest of the larger communications network).

UE device 10 of FIG. 1 is an electronic device (sometimes referred to herein as electronic device 10 or device 10) and may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses, goggles, or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, UE device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, part or all of housing 12 may be formed from dielectric or other low-conductivity material (e.g., glass, ceramic, plastic, sapphire, etc.). In other situations, housing 12 or at least some of the structures that make up housing 12 may be formed from metal elements.

UE device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within UE device 10 and/or removable storage media.

Control circuitry 14 may include processing circuitry such as processing circuitry 18. Processing circuitry 18 may be used to control the operation of UE device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in UE device 10 using hardware (e.g., dedicated hardware or circuitry), firmware, and/or software. Software code for performing operations in UE device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on UE device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol.

UE device 10 may include input-output circuitry 20. Input-output circuitry 20 may include input-output devices 22. Input-output devices 22 may be used to allow data to be supplied to UE device 10 and to allow data to be provided from UE device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), temperature sensors, etc. In some configurations, keyboards, headphones, displays, pointing devices such as trackpads, mice, and joysticks, and other input-output devices may be coupled to UE device 10 using wired or wireless connections (e.g., some of input-output devices 22 may be peripherals that are coupled to a main processing unit or other portion of UE device 10 via a wired or wireless link).

Input-output circuitry 20 may include wireless circuitry 24 to support wireless communications. Wireless circuitry 24 (sometimes referred to herein as wireless communications circuitry 24) may include one or more antennas 30.

Wireless circuitry 24 may also include transceiver circuitry 26. Transceiver circuitry 26 may include transmitter circuitry, receiver circuitry, modulator circuitry, demodulator circuitry (e.g., one or more modems), radio-frequency circuitry, one or more radios, intermediate frequency circuitry, optical transmitter circuitry, optical receiver circuitry, optical light sources, other optical components, baseband circuitry (e.g., one or more baseband processors), amplifier circuitry, clocking circuitry such as one or more local oscillators and/or phase-locked loops, memory, one or more registers, filter circuitry, switching circuitry, analog-to-digital converter (ADC) circuitry, digital-to-analog converter (DAC) circuitry, radio-frequency transmission lines, optical fibers, and/or any other circuitry for transmitting and/or receiving wireless signals using antennas 30. The components of transceiver circuitry 26 may be implemented on one integrated circuit, chip, system-on-chip (SOC), die, printed circuit board, substrate, or package, or the components of transceiver circuitry 26 may be distributed across two or more integrated circuits, chips, SOCs, printed circuit boards, substrates, and/or packages.

The example of FIG. 1 is merely illustrative. While control circuitry 14 is shown separately from wireless circuitry 24 in the example of FIG. 1 for the sake of clarity, wireless circuitry 24 may include processing circuitry (e.g., one or more processors) that forms a part of processing circuitry 18 and/or storage circuitry that forms a part of storage circuitry 16 of control circuitry 14 (e.g., portions of control circuitry 14 may be implemented on wireless circuitry 24). As an example, control circuitry 14 may include baseband circuitry (e.g., one or more baseband processors), digital control circuitry, analog control circuitry, and/or other control circuitry that forms part of wireless circuitry 24. The baseband circuitry may, for example, access a communication protocol stack on control circuitry 14 (e.g., storage circuitry 16) to: perform user plane functions at a PHY layer, MAC layer, RLC layer, PDCP layer, SDAP layer, and/or PDU layer, and/or to perform control plane functions at the PHY layer, MAC layer, RLC layer, PDCP layer, RRC, layer, and/or non-access stratum layer.

Transceiver circuitry 26 may be coupled to each antenna 30 in wireless circuitry 24 over a respective signal path 28. Each signal path 28 may include one or more radio-frequency transmission lines, waveguides, optical fibers, and/or any other desired lines/paths for conveying wireless signals between transceiver circuitry 26 and antenna 30. Antennas 30 may be formed using any desired antenna structures for conveying wireless signals. For example, antennas 30 may include antennas with resonating elements that are formed from dipole antenna structures, planar dipole antenna structures (e.g., bowtie antenna structures), slot antenna structures, loop antenna structures, patch antenna structures, inverted-F antenna structures, planar inverted-F antenna structures, helical antenna structures, monopole antennas, dipoles, hybrids of these designs, etc. Filter circuitry, switching circuitry, impedance matching circuitry, and/or other antenna tuning components may be adjusted to adjust the frequency response and wireless performance of antennas 30 over time.

If desired, two or more of antennas 30 may be integrated into a phased antenna array (sometimes referred to herein as a phased array antenna or an array of antenna elements) in which each of the antennas conveys wireless signals with a respective phase and magnitude that is adjusted over time so the wireless signals constructively and destructively interfere to produce (form) a signal beam in a given pointing direction. The term “convey wireless signals” as used herein means the transmission and/or reception of the wireless signals (e.g., for performing unidirectional and/or bidirectional wireless communications with external wireless communications equipment). Antennas 30 may transmit the wireless signals by radiating the signals into free space (or to free space through intervening device structures such as a dielectric cover layer). Antennas 30 may additionally or alternatively receive the wireless signals from free space (e.g., through intervening devices structures such as a dielectric cover layer). The transmission and reception of wireless signals by antennas 30 each involve the excitation or resonance of antenna currents on an antenna resonating (radiating) element in the antenna by the wireless signals within the frequency band(s) of operation of the antenna.

Transceiver circuitry 26 may use antenna(s) 30 to transmit and/or receive wireless signals that convey wireless communications data between UE device 10 and external wireless communications equipment (e.g., one or more other devices such as UE device 10, a wireless access point or base station, etc.). The wireless communications data may be conveyed bidirectionally or unidirectionally. The wireless communications data may, for example, include data that has been encoded into corresponding data packets such as wireless data associated with a telephone call, streaming media content, internet browsing, wireless data associated with software applications running on UE device 10, email messages, etc.

Additionally or alternatively, wireless circuitry 24 may use antenna(s) 30 to perform wireless sensing operations. The sensing operations may allow UE device 10 to detect (e.g., sense or identify) the presence, location, orientation, and/or velocity (motion) of objects external to UE device 10. Control circuitry 14 may use the detected presence, location, orientation, and/or velocity of the external objects to perform any desired device operations. As examples, control circuitry 14 may use the detected presence, location, orientation, and/or velocity of the external objects to identify a corresponding user input for one or more software applications running on UE device 10 such as a gesture input performed by the user's hand(s) or other body parts or performed by an external stylus, gaming controller, head-mounted device, or other peripheral devices or accessories, to determine when one or more antennas 30 needs to be disabled or provided with a reduced maximum transmit power level (e.g., for satisfying regulatory limits on radio-frequency exposure), to determine how to steer (form) a radio-frequency signal beam produced by antennas 30 for wireless circuitry 24 (e.g., in scenarios where antennas 30 include a phased array of antennas 30), to map or model the environment around UE device 10 (e.g., to produce a software model of the room where UE device 10 is located for use by an augmented reality application, gaming application, map application, home design application, engineering application, etc.), to detect the presence of obstacles in the vicinity of (e.g., around) UE device 10 or in the direction of motion of the user of device 10, etc. The sensing operations may, for example, involve the transmission of sensing signals (e.g., radar waveforms), the receipt of corresponding reflected signals (e.g., the transmitted waveforms that have reflected off of external objects), and the processing of the transmitted signals and the received reflected signals (e.g., using a radar scheme).

Wireless circuitry 24 may transmit and/or receive wireless signals within corresponding frequency bands of the electromagnetic spectrum (sometimes referred to herein as communications bands or simply as “bands”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

Over time, software applications on electronic devices such as UE device 10 have become more and more data intensive. Wireless circuitry on the electronic devices therefore needs to support data transfer at higher and higher data rates. In general, the data rates supported by the wireless circuitry are proportional to the frequency of the wireless signals conveyed by the wireless circuitry (e.g., higher frequencies can support higher data rates than lower frequencies). Wireless circuitry 24 may convey centimeter and millimeter wave signals to support relatively high data rates (e.g., because centimeter and millimeter wave signals are at relatively high frequencies between around 10 GHz and 100 GHz). To support even higher data rates such as data rates up to 5-100 Gbps or higher, wireless circuitry 24 may convey wireless signals at frequencies greater than about 100 GHz.

As shown in FIG. 1, wireless circuitry 24 may transmit wireless (radio-frequency) signals 32 and/or may receive wireless signals 32 at frequencies greater than around 10 GHz (e.g., greater than 20 GHz, greater than 30 GHz, greater than 70 GHz, 80 GHz, 90 GHz, 110 GHz, etc.). Wireless signals 32 may, for example, millimeter wave signals, centimeter wave signals, tremendously high frequency (THF) signals, sub-THz signals, THz signals, or sub-millimeter wave signals. In other words, wireless signals 32 may be at centimeter wave frequencies (e.g., around 10-30 GHz), millimeter wave frequencies (e.g., around 30-100 GHz), and/or sub-THz or THz frequencies such as frequencies between 100 GHz and 1 THz (e.g., within a sub-THz, THz, THF, or sub-millimeter frequency band such as a 6G frequency band). The high data rates supported by these frequencies may be leveraged by UE device 10 to perform cellular telephone voice and/or data communications (e.g., while supporting spatial multiplexing to provide further data bandwidth), to perform spatial ranging operations such as radar operations to detect the presence, location, and/or velocity of objects external to UE device 10, to perform automotive sensing (e.g., with enhanced security), to perform health/body monitoring on a user of UE device 10 or another person, to perform gas or chemical detection, to form a high data rate wireless connection between device 10 and another device or peripheral device (e.g., to form a high data rate connection between a display driver on UE device 10 and a display that displays ultra-high resolution video), to form a remote radio head (e.g., a flexible high data rate connection), to form a THF chip-to-chip connection within UE device 10 that supports high data rates (e.g., where one antenna 30 on a first chip in UE device 10 transmits wireless signals 32 to another antenna 30 on a second chip in UE device 10), and/or to perform any other desired high data rate operations.

Space is at a premium within electronic devices such as device 10. In some scenarios, different antennas 30 are used to transmit wireless signals 32 than are used to receive wireless signals 32. However, handling transmission of wireless signals 32 and reception of wireless signals 32 using different antennas 30 can consume an excessive amount of space and other resources within device 10 because two antennas 30 and signal paths 28 would be required to handle both transmission and reception. To minimize space and resource consumption within device 10, the same antenna 30 and signal path 28 may be used to both transmit wireless signals 32 and to receive wireless signals 32. If desired, multiple antennas 30 in wireless circuitry 24 may transmit wireless signals 32 and may receive wireless signals 32. The antennas may be integrated into a phased antenna array that transmits wireless signals 32 and that receives wireless signals 32 within a corresponding signal beam oriented in a selected beam pointing direction.

As shown in FIG. 1, BS 6 may also include control circuitry 14′ (e.g., control circuitry having similar components and/or functionality as control circuitry 14 in UE device 10) and wireless circuitry 24′ (e.g., wireless circuitry having similar components and/or functionality as wireless circuitry 24′ in UE device 10). Wireless circuitry 24′ may include transceiver circuitry 26′ (e.g., transceiver circuitry having similar components and/or functionality as transceiver circuitry 26 in UE device 10) coupled to two or more antennas 30′ (e.g., antennas having similar components and/or functionality as antennas 30 in UE device 10) over corresponding signal paths 28′ (e.g., signal paths having similar components and/or functionality as signal paths 28 in UE device 10). Antennas 30′ may be arranged in one or more phased antenna arrays. BS 6 may use wireless circuitry 24′ to transmit wireless signals 32 to UE device 10 (e.g., as downlink (DL) signals transmitted in downlink direction 31) and/or to receive wireless signals 32 transmitted by UE device 10 (e.g., as uplink (UL) signals transmitted in uplink direction 29).

The antennas 30′ in BS 6 and/or the antennas 30 in UE device 10 may be arranged into one or more phased antenna arrays for conveying wireless signals 32. Conveying wireless signals 32 using phased antenna arrays may allow for greater peak signal gain relative to scenarios where individual antennas are used to convey the wireless signals. In satellite navigation system links, cellular telephone links, and other long-range links, radio-frequency signals are typically used to convey data over thousands of feet or miles. In Wi-Fi® and Bluetooth® links at 2.4 and 5 GHz and other short-range wireless links, radio-frequency signals are typically used to convey data over tens or hundreds of feet. In scenarios where millimeter wave, centimeter wave, sub-THz, or THz frequencies are used to convey wireless signals 32, a phased antenna array may convey radio-frequency signals over short distances that travel over a line-of-sight (LOS) path. To enhance signal reception for millimeter wave, centimeter wave, sub-THz, and THz communications, the phased antenna array may convey wireless signals 32 using beam steering techniques (e.g., schemes in which antenna signal phase and/or magnitude for each antenna in an array are adjusted to perform beam steering).

The term “beam” or “signal beam” may be used herein to collectively refer to wireless signals 32 that are transmitted and/or received by a phased antenna array (e.g., in BS 6 and/or UE device 10) in a particular direction. Each signal beam may exhibit a peak gain that is oriented in a respective beam pointing direction (sometimes referred to herein as a steering direction) at a corresponding beam pointing (steering) angle (e.g., based on constructive and destructive interference from the combination of signals from each antenna in the phased antenna array). Phase and magnitude controllers coupled to the antennas in the phased antenna array may be adjusted between different sets of phase and magnitude settings to configure the phased antenna array to form different signal beams in different beam pointing directions (e.g., to steer or sweep the signal beam over or in different directions).

The signal beams formed or formable by a phased antenna array on BS 6 (e.g., a phased antenna array of antennas 30′) may sometimes be referred to herein as BS beams. The signal beams formed or formable by a phased antenna array on UE device 10 (e.g., a phased antenna array of antennas 30) may sometimes be referred to herein as UE beams. UE device 10 may have or store a codebook (sometimes referred to herein as a UE codebook) that maps the phase and magnitude settings for each antenna 30 in the phased antenna array to different UE beams formed by the phased antenna array when configured using those phase and magnitude settings. In other words, the UE codebook may store all UE beams formable by the phased antenna array as well as the phase and magnitude settings used by the antennas 30 in the phased antenna array to form those UE beams. Similarly, BS 6 may have or store a codebook (sometimes referred to herein as a BS codebook) that maps the phase and magnitude settings for each antenna 30′ in the phased antenna array to different BS beams formed by the phased antenna array when configured using those phase and magnitude settings. In other words, the BS codebook may store all BS beams formable by the phased antenna array as well as the phase and magnitude settings used by the antennas 30′ in the phased antenna array to form those BS beams.

To perform wireless communications, UE device 10 may first connect to or register with BS 6. The relative position/orientation of UE device 10 relative to BS 6 in system 4 may initially be unknown to UE device 10 and/or BS 6. As such, UE device 10 may have no initial knowledge of which UE beam will point towards BS 6 and BS 6 may have no initial knowledge of which BS beam will point towards UE device 10. Upon initial connection/registration, after UE device 10 has moved (e.g., in a UE mobility scenario), periodically, and/or in response to any desired trigger condition, UE device 10 and BS 6 may perform a beam training or discovery operation to detect the optimal UE beam (e.g., the UE beam of UE device 10 that points towards BS 6) and the optimal BS beam (e.g., the BS beam of BS 6 that points towards UE device 10) for conveying wireless data between BS 6 and UE device 10. Once UE device 10 has discovered the optimal UE beam and BS 6 has discovered the optimal BS beam, UE device 10 may connect/register to BS 6, UE device 10 may use the optimal UE beam, and BS 6 may use the optimal BS beam to convey wireless data (e.g., using wireless signals 32).

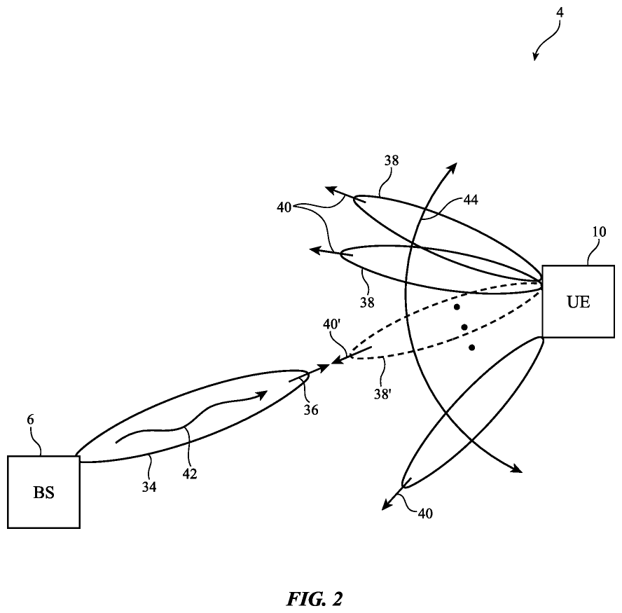

UE device 10 and BS 6 may perform the beam training operation during a beam training period sometimes referred to as a beam training interval. The beam training interval may, for example, be specified by the communications protocol governing wireless signals 32. FIG. 2 is a diagram showing one example of how UE device 10 and BS 6 may perform beam training during a beam training interval.

As shown in FIG. 2, BS 6 may form a BS beam 34 (e.g., in a corresponding beam pointing direction 36). UE device 10 may form a UE beam 38 from the set of UE beams formable by UE device 10 at any given time. Each UE beam 38 may have a different corresponding beam pointing direction 40. During the beam training interval, BS 6 transmit reference signals 42 over BS beam 34 (e.g., holding the BS beam fixed without sweeping over different BS beams). The reference signals may include a set of reference symbols (sometimes referred to herein as training symbols or training reference symbols).

While BS 6 transmits reference signals 42 over BS beam 34, UE device 10 may sweep the phased antenna array of antennas 30 over a set of different UE beams 38 formable by the phased antenna array (as shown by arrow 44). Transceiver circuitry 26 on UE device 10 may listen for reference signals 42 while sweeping over the set of UE beams 38. Transceiver 26 may listen for reference signals by receiving radio-frequency energy over each UE beam 38 in the sweep and measuring wireless performance metric data while each UE beam in the sweep is formed by the phased antenna array.

As used herein, the term “wireless performance metric data” refers to measurements or values of one or more wireless performance metrics (e.g., key performance indicators (KPI's)) that are generated by radio-frequency circuitry (e.g., receiver circuitry, transmitter circuitry, transceiver circuitry, coupler circuitry, impedance measurement circuitry, radio-frequency sensor circuitry, one or more radios, etc.) and/or processing circuitry (e.g., baseband circuitry, an application processor, one or more processors, etc.) in response to, using, or based on transmitted and/or received radio-frequency signals and/or the wireless data conveyed by the radio-frequency signals. The wireless performance metric data may characterize the radio-frequency propagation conditions or channel conditions of the radio-frequency signals and/or the wireless performance of wireless circuitry on UE device 10 and/or BS 6 in conveying radio-frequency signals and/or wireless data. The wireless performance metric data may include, as examples, received power levels, transmit power levels, received signal strength indicator (RSSI) values, reference signal received power (RSRP) values, received signal code power (RSCP) information, error rate values (e.g., bit error rate values, frame error rate values, block error rate values, etc.), quality factor (Q) values, adjacent channel leakage ratio (ACLR) values or other spectral measurement values, error vector magnitude (EVM) values, radio-frequency channel measurements (e.g., channel coefficient magnitude and/or phase measurements), receiver sensitivity values, noise floor values or other signal noise levels, signal-to-noise ratio (SNR) values, signal-to-interference-and-noise ratio (SINR) values, Ec/IO data, Ec/No data, combinations of these and/or other values, and/or measurements of any other desired wireless performance metrics, criteria, or indicators.

Once UE device 10 has gathered (measured) wireless performance metric data using each UE beam 38 in the sweep, UE device 10 may process the wireless performance metric data to identify the optimal UE beam for use in communicating with BS 6. For example, UE device 10 may identify the UE beam 38 that produced the optimal (strongest) wireless performance metric data as the optimal UE beam (e.g., optimal UE beam 38′ having a beam pointing direction 40′ pointing towards BS 6). UE device 10 and BS 6 may then use BS beam 34 and optimal UE beam 38′ to convey wireless data until UE device 10 moves/rotates, the next beam training interval, etc.

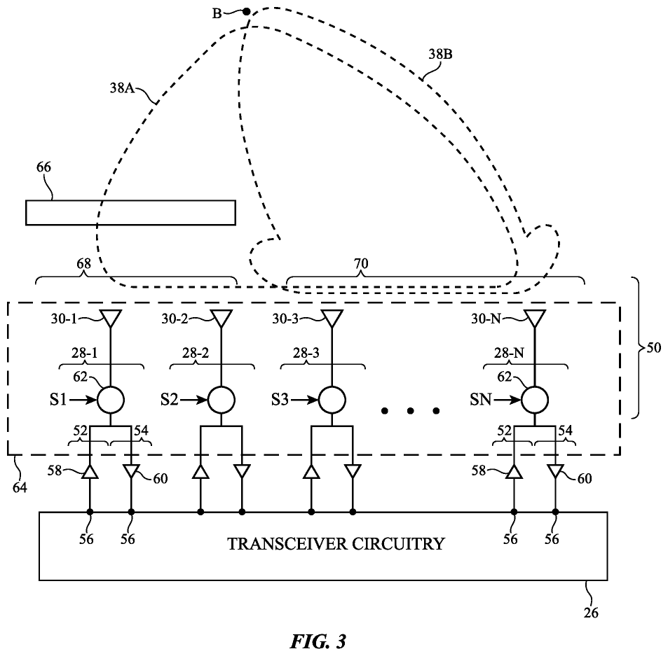

FIG. 3 is a circuit diagram showing how antennas 30 in UE device 10 may be arranged in a corresponding phased antenna array 50. As shown in FIG. 3, phased antenna array 50 may include N total antennas 30 (e.g., a first antenna 30-1, a second antenna 30-2, a third antenna 30-3, an Nth antenna 30-N, etc.). The N antennas 30 in phased antenna array 50 may be arranged in a one-dimensional pattern (e.g., along a line), in a two-dimensional pattern (e.g., a grid having rows and columns, a circular or hexagonal grid, etc.), or in other patterns. N may be any desired integer greater than or equal to two (e.g., three, four, five, six, seven, eight, more than eight, twelve, sixteen, etc.). Implementations in which N≥4 are sometimes described herein as an example (e.g., as shown in FIG. 3).

Each antenna 30 in phased antenna array 50 (sometimes referred to herein as array 50, antenna array 50, or array 50 of antennas 30) may be coupled to one or more respective ports 56 of transceiver circuitry 26 over signal paths 28. For example, antenna 30-1 in phased antenna array 50 may be coupled to transceiver circuitry 26 over a first signal path 28-1, antenna 30-2 in phased antenna array 50 may be coupled to transceiver circuitry 26 over a second signal path 28-2, antenna 30-3 in phased antenna array 50 may be coupled to transceiver circuitry 26 over a third signal path 28-3, antenna 30-N may be coupled to transceiver circuitry 26 over an Nth signal path 32-N, etc. While antennas 30 are described herein as forming a phased antenna array, the antennas 30 in phased antenna array 50 may sometimes also be referred to as collectively forming a single phased array antenna (e.g., where antennas 30 form antenna elements of the phased array antenna).

If desired, transceiver circuitry 26 may include a signal combiner (e.g., a signal adder) having inputs coupled to all of the ports 56 of transceiver circuitry 26 (not shown in FIG. 3 for the sake of clarity). The signal combiner may, for example, combine the signals received over all N signal paths 28 together before passing the combined signals to other circuitry in transceiver circuitry 26 (e.g., mixer circuitry, low noise amplifier circuitry, demodulator circuitry, etc.). Conversely, during signal transmission, the signal combiner may act as a signal splitter. The signal splitter may, for example, receive radio-frequency signals for transmission and may transmit/split the radio-frequency signals over each of the N signal paths 28. Alternatively, transceiver circuitry 26 may include a signal splitter coupled to transmit (TX) chains 52 of signal paths 28 (e.g., to transmit ports 56 of transceiver circuitry 26) and may include a separate signal combiner coupled to receive (RX) chains 54 of signal paths 28 (e.g., to receive ports 56 of transceiver circuitry 26).

The antennas 30 in phased antenna array 50 may be arranged in any desired number of rows and columns or in any other desired pattern (e.g., the antennas need not be arranged in a grid pattern having rows and columns). Each antenna 30 may be separated from one or more adjacent antennas 30 in phased antenna array 50 by a predetermined distance such as approximately half an effective wavelength of operation of the array. During signal transmission, signal paths 28 may be used to supply signals (e.g., radio-frequency signals such as wireless signals 32 of FIG. 1) from transceiver circuitry 26 to phased antenna array 50 for wireless transmission. During signal reception, signal paths 28 may be used to supply signals received at phased antenna array 50 (e.g., from BS 6) to transceiver circuitry 26.

If desired, the N antennas 30 in phased antenna array 50 may be disposed on a single underlying substrate 64 (e.g., a printed circuit substrate) to implement the phased antenna array within or as a single antenna module, antenna panel, or antenna package. Substrate 64 may, for example, be free from antennas other than the N antennas that form phased antenna array 50 (e.g., substrate 64 may be free from antennas that form part of phased antenna arrays other than phased antenna array 50). Phased antenna array 50 may therefore sometimes be referred to herein as antenna module 50, antenna package 50, or antenna panel (AP) 50.

The use of multiple antennas 30 in phased antenna array 50 allows beam forming/steering arrangements to be implemented by controlling the relative phases and magnitudes (amplitudes) of the radio-frequency signals conveyed by the antennas. In the example of FIG. 3, the signal path 28 for each antenna 30 in phased antenna array 50 has a corresponding radio-frequency phase and magnitude controller 62 disposed thereon. Phase and magnitude controllers 62 may each include circuitry for adjusting the phase of the radio-frequency signals on the corresponding signal path 28 (e.g., radio-frequency phase shifter (PS) circuits) and/or circuitry for adjusting the magnitude of the radio-frequency signals on the corresponding signal path 28 (e.g., one or more power amplifiers, one or more low noise amplifiers, and/or one or more signal attenuators). Signal attenuators in phase and magnitude controllers 62 (e.g., passive signal attenuators such as resistive signal attenuators, pi-attenuators, etc.) may, for example, help to tweak the signal level (magnitude or amplitude) of the radio-frequency signals conveyed by each antenna 30 to different desired values that serve to maximize the overall signal-to-noise-and-distortion ratio (SNDR) of the received signals (e.g., to perform gain-tapering that provides spatial filtering for phased antenna array 50, to tweak the shape and/or orientation of the UE beam in a manner that prevents the reception of unwanted jammer signals received from directions other than the beam pointing direction, etc.). The N phase and magnitude controllers 62 across phased antenna array 50 may sometimes be referred to collectively herein as beam steering circuitry or beam forming circuitry (e.g., beam steering/forming circuitry that steers/forms the beam of radio-frequency signals transmitted and/or received by phased antenna array 50).

As shown in FIG. 3, each signal path 28 in phased antenna array 50 may include a corresponding receive (RX) chain 54 (sometimes referred to herein as receive path 54) and a corresponding transmit (TX) chain 52 (sometimes referred to herein as transmit path 52). Filter circuitry and/or switching circuitry (not shown in FIG. 3 for the sake of clarity) may be used to couple both the RX chain 54 and the TX chain 52 of a given signal path 28 to the corresponding antenna 30. The phase and magnitude controller 62 of each signal path 28 may be coupled between the RX chain 54, the TX chain 52, and the antenna 30 of that signal path 28. If desired, some or all of phase and magnitude controller 62 may be disposed in RX chain 54 and/or TX chain 52.

During signal reception, each antenna 30 receives radio-frequency signals (e.g., wireless signals 32 of FIG. 1) and passes the received radio-frequency signals onto its corresponding signal path 28. The received signals are initially incoherent across phased antenna array 50. Phase and magnitude controllers 62 may adjust the phase and/or magnitude of the received signals by different amounts across phased antenna array 50 (e.g., using different phase and/or magnitude settings) to align the phases of the received signals across phased antenna array 50 (e.g., making the N received signals coherent with each other prior to passing the received signals to transceiver circuitry 26). The phase and magnitude controller 62 on each signal path 28 may pass the received radio-frequency signals to the corresponding RX chain 54 of that signal path 28. Each RX chain 54 may pass the received radio-frequency signals to a corresponding (respective) port 56 of transceiver circuitry 26. Each RX chain 54 may include one or more low noise amplifiers 60 and/or any other desired radio-frequency circuitry that operates on the radio-frequency signals passed by the corresponding signal chain 28 to transceiver circuitry 26.

During signal transmission, transceiver circuitry 26 transmits radio-frequency signals (e.g., wireless signals 32 of FIG. 1) onto the N signal paths 28 of phased antenna array 50. The radio-frequency signals may, for example, include or carry N copies of the same wireless data to be transmitted. Each TX chain 52 may pass the radio-frequency signals to its corresponding phase and magnitude controller 62. Each TX chain 52 may include one or more power amplifiers 58 and/or any other desired radio-frequency circuitry that operates on the radio-frequency signals passed by the corresponding signal chain 28 from transceiver circuitry 26 to the corresponding antenna 30. Phase and magnitude controllers 62 may adjust the phase and/or magnitude of the transmitted radio-frequency signals by different amounts across phased antenna array 50 (e.g., using different phase and/or magnitude settings) to cause the radio-frequency signals, when radiated by antennas 30, to constructively and destructively interfere in a manner that produces the corresponding UE beam oriented in the corresponding beam pointing direction.

While shown as separate from phase and magnitude controllers 62 for the sake of clarity, the power amplifier(s) 58 and/or the low noise amplifier(s) 60 on a given signal path 28 may form part of the phase and magnitude controller 62 on the given signal path 28 if desired (e.g., power amplifier(s) 58 and/or low noise amplifier(s) 60 may be used to perform beam forming). If desired, phase shifters in phase and magnitude controller 62 may be coupled between power amplifier(s) 58 and transceiver circuitry 26 and/or between low noise amplifier(s) 60 and transceiver circuitry 26. If desired, portions of TX chain 52 and/or RX chain 54 (e.g., power amplifier(s) 58 and/or low noise amplifier(s) 60) may be implemented within transceiver circuitry 26.

If desired, one or more antenna activation switches (not shown in FIG. 3 for the sake of clarity) may be disposed at one or more points along each signal path 28 (e.g., on TX chain 52, on RX chain 54, between amplifiers 58 and/or 60 and transceiver circuitry 26, between amplifiers 58 and/or 60 and phase and magnitude controller 62, within amplifiers 58 and/or 60, within phase and magnitude controller 62, and/or between phase and magnitude controller 62 and the corresponding antenna 30). The antenna activation switch may be toggled (e.g., using a control signal received from control circuitry 14 of FIG. 1) to place the switch in a first state (e.g., a closed, active, enabled, or “on” state) or in a second state (e.g., an open, inactive, disabled, or “off” state). When the antenna activation switch is in the first state (e.g., activated, enabled, closed, or turned on), the antenna activation switch may form a minimal impedance (e.g., a zero or short circuit impedance) for the radio-frequency signals conveyed its signal path 28 and the radio-frequency signals may pass through the antenna activation switch (e.g., along signal path 28 between antenna 30 and transceiver circuitry 26). The corresponding antenna 30 may, for example, convey radio-frequency signals while the antenna activation switch is in the first state. When the antenna activation switch is in the second state (e.g., deactivated, disabled, open, or turned off), the antenna activation switch may form a maximal impedance (e.g., an infinite or open circuit impedance) for the radio-frequency signals conveyed over its signal path 28 and the radio-frequency signals do not pass through the antenna activation switch. The corresponding antenna 30 may, for example, not convey any radio-frequency signals while the antenna activation switch is in the second state.

Phase and magnitude controllers 62 may adjust the relative phases and/or magnitudes of the transmitted signals that are provided to each of the antennas in phased antenna array 50 and may adjust the relative phases and/or magnitudes of the received signals that are received by phased antenna array 50 when performing beam forming. Each signal beam of phased antenna array 50 (e.g., each UE beam) may exhibit a peak gain that is oriented in a different respective beam pointing direction (e.g., beam pointing directions 40 of FIG. 2) at a corresponding beam pointing angle (e.g., based on constructive and destructive interference from the combination of signals from each antenna in the phased antenna array). Different sets of phase and magnitude settings for phase and magnitude controllers 62 may configure phased antenna array 50 to form different beams in different beam pointing directions.

If, for example, phase and magnitude controllers 62 are adjusted to produce a first set of phases and/or magnitudes, the signals will form a UE beam that is oriented in the direction of point A. If, however, phase and magnitude controllers 62 are adjusted to produce a second set of phases and/or magnitudes, the signals will form a UE beam that is oriented in the direction of point B. Each phase and magnitude controller 62 may be controlled to produce a desired phase and/or magnitude based on a corresponding control signal S received from control circuitry 14 of FIG. 1 (e.g., the phase and/or magnitude provided by the phase and magnitude controller 62 on signal path 28-1 may be controlled using control signal S1, the phase and/or magnitude provided by the phase and magnitude controller 62 on signal path 28-2 may be controlled using control signal S2, the phase and/or magnitude provided by the phase and magnitude controller 62 on signal path 28-3 may be controlled using control signal S3, the phase and/or magnitude provided by the phase and magnitude controller 62 on signal path 28-N may be controlled using control signal SN, etc.). If desired, the control circuitry may actively adjust control signals S in real time to steer (form) the UE beam in different desired directions over time.

When performing wireless communications using radio-frequency signals at relatively high frequencies such as millimeter wave, centimeter wave, sub-THz, or THz frequencies, radio-frequency signals are conveyed over a line-of-sight path between phased antenna array 50 and external communications equipment (e.g., BS 6). If the external equipment is located at point A, phase and magnitude controllers 62 may be adjusted to steer the signal beam towards point A (e.g., to steer the pointing direction of the UE beam towards point A). Phased antenna array 50 may transmit and receive radio-frequency signals in the direction of point A. Similarly, if the external equipment is located at point B, phase and magnitude controllers 62 may be adjusted to steer the signal beam towards point B (e.g., to steer the pointing direction of the UE beam towards point B). Phased antenna array 50 may transmit and receive radio-frequency signals in the direction of point B.

In the example of FIG. 3, beam steering is shown as being performed over a single degree of freedom for the sake of simplicity (e.g., towards the left and right on the page of FIG. 3). However, in practice, the beam may be steered over two or more degrees of freedom (e.g., in three dimensions, into and out of the page and to the left and right on the page of FIG. 3). Phased antenna array 50 may have a corresponding field of view over which beam steering can be performed (e.g., in a hemisphere or a segment of a hemisphere over the phased antenna array).

In practice, some or all of phased antenna array 50 may become fully or partially blocked by external objects during operation. For example, as shown in FIG. 3, an external object 66 may block, cover, or overlap a first set of antennas 30 in phased antenna array 50 such as antennas 30-1 and 30-2. External object 66 may be, for example, furniture (e.g., a table top), a body or body part, clothing, an animal, a credit card attached to the back of UE device 10, a wall or corner of a room, a cubicle wall, a vehicle, a landscape feature, a case, or other obstacles. Antennas 30 that are blocked by external object 66 (e.g., such that external object 66 causes the wireless performance of the antennas or UE device 10 in communicating using the antennas to fall below a threshold level) may sometimes be referred to herein as blocked antennas 30 or covered antennas 30. Antennas 30 that are not blocked by external object 66 (e.g., such that external object 66 causes the wireless performance of the antennas or UE device 10 in communicating using the antennas is above a threshold level) may sometimes be referred to herein as unblocked antennas 30 or uncovered antennas 30.

When external objects such as external object 66 block part of phased antenna array 50 (e.g., the antenna panel), if care is not taken, it can be difficult to maintain satisfactory wireless communications between UE device 10 and BS 6. For example, the presence of external object 66 can impact the reliability of power amplifiers 58 by causing transmitted signals to be reflected at blocked antennas 30 back towards the output of the power amplifiers, which can damage transistors in the power amplifiers. In addition, blocked antennas 30 can cause phased antenna array 50 to consume an excessive amount of power, thereby limiting battery life, since wireless data conveyed using the blocked antennas is unlikely to be successfully received. Further, blocked antennas 30 can limit the overall signal-to-noise ratio (SNR) and thus the sensitivity of phased antenna array 50 because the blocked antennas contribute full noise but very little signal.

To mitigate these issues while maximizing wireless performance and minimizing power consumption under different environmental conditions (e.g., as the presence of external object 66 nearby phased antenna array 50 changes over time), control circuitry 14 (FIG. 1) may perform phased antenna array tapering operations on phased antenna array 50 (sometimes referred to herein as hard tapering or simply as array tapering). Control circuitry 14 may perform array tapering by identifying a first set of the N antennas 30 in phased antenna array 50 (e.g., the antenna panel) and then disabling the first set of antennas from conveying radio-frequency signals during subsequent communications. At the same time, a second set of the N antennas 30 (e.g., the remaining antennas 30 in phased antenna array 50 that do not include the first set of antennas) may continue to convey radio-frequency signals during the subsequent communications.

Control circuitry 14 may disable the first set of antennas 30 by powering down or powering off the power amplifier(s) 58 and/or low noise amplifier(s) 60 coupled to the antennas 30 in the first set, by turning off (opening) one or more antenna activation switches disposed on the signal paths 28 coupled to the antennas 30 in the first set (e.g., forming open circuit impedances for radio-frequency signals the along signal paths 28 coupled to the antennas 30 in the first set), by disabling (e.g., deactivating, turning off, switching off, etc.) the ports 56 of transceiver circuitry 26 coupled to the antennas 30 in the first set, by disabling (e.g., deactivating, switching off, powering down, powering off, etc.) portions of transceiver circuitry 26, and/or using any other desired techniques. The antennas 30 that have been disabled (e.g., the antennas 30 in the first set) may sometimes also be referred to herein as disabled antennas 30, deactivated antennas 30, inactive antennas 30, switched off antennas 30, powered off antennas 30, muted antennas 30, or unpowered antennas 30. The signal paths 28 coupled to the antennas 30 that have been disabled (e.g., the signal paths 28 of the first set of antennas 30) may sometimes also be referred to herein as disabled signal paths 28, deactivated signal paths 28, inactive signal paths 28, muted signal paths 28, switched off signal paths 28, powered off signal paths 28, or unpowered signal paths 28. Disabled antennas 30 and disabled signal paths 28 (e.g., the first set of antennas 30 and the corresponding signal paths 28) do not actively convey radio-frequency signals (e.g., are inactive, deactivated, or disabled) even when radio-frequency signals are incident upon those antennas 30 and even when transceiver circuitry 26 is otherwise transmitting radio-frequency signals using the second set of antennas 30.

The antennas 30 that are enabled (e.g., the antennas 30 in the second set) may sometimes also be referred to herein as enabled antennas 30, active antennas 30, activated antennas 30, switched on antennas 30, powered on antennas 30, unmuted antennas 30, or powered antennas 30. The signal paths 28 coupled to the antennas 30 that have been enabled (e.g., the signal paths 28 of the second set of antennas 30) may sometimes also be referred to herein as enabled signal paths 28, activated signal paths 28, active signal paths 28, switched on signal paths 28, powered on signal paths 28, unmuted signal paths 28 or powered signal paths 28. Enabled antennas 30 and enabled signal paths 28 (e.g., the second set of antennas 30 and the corresponding signal paths 28) may actively convey radio-frequency signals (e.g., as the radio-frequency signals are incident upon those antennas 30 and/or transmitted by transceiver circuitry 26). Antennas 30 and some or all of signal paths 28 that have been disabled may, for example, consume no current or minimal current (e.g., current less than a threshold value). On the other hands, antennas 30 and signal paths 28 that are enabled may, for example, consume non-zero current or a relatively high amount of current (e.g., current exceeding a threshold value).

Once the first set of antennas 30 has been disabled, transceiver circuitry 26 may then convey radio-frequency signals using the second set of antennas 30. When all N antennas 30 are active in phased antenna array 50, the phase and magnitude of each antenna may contribute to the overall UE beam formed by phased antenna array 50, as shown by UE beam 38A (sometimes referred to herein as full-array beam 38A or untapered beam 38A). However, when the first set of N antennas 30 are disabled, beamforming is only performed by the second set of antennas 30 that remain enabled. The second set of antennas 30 may, for example, be provided with phase and magnitude settings (e.g., using the phase and magnitude controllers 62 of the second set of antennas 30) that configure only the second set of antennas 30 to form the UE beam for phased antenna array 50 (e.g., without any constructive/destructive interference contribution from the first set of antennas 30, which do not convey radio-frequency signals when disabled), as shown by UE beam 38B. UE beam 38B may sometimes also be referred to herein as subarray beam 38A or tapered beam 38B.

Consider the example of FIG. 3 in which external object 66 covers, overlaps, blocks, or excessively deteriorates the wireless performance of antennas 30-1 and 30-2 without overlapping, covering, blocking, or excessively deteriorating the wireless performance of the remaining antennas 30 in phased antenna array 50. In this example, control circuitry 14 may identify antennas 30-1 and 30-2 as forming the first set of antennas 30 (sometimes referred to herein as first set 68) to disable for subsequent communications and may identify the remaining antennas 30 in phased antenna array 50 as forming the second set of antennas 30 (sometimes referred to herein as second set 70) to keep enabled for subsequent communications. While referred to herein as sets, sets 68 and 70 may sometimes also be referred to herein as groups, subsets, or subarrays of antennas 30 in phased antenna array 50 (e.g., where the number of antennas in first set 68 plus the number of antennas in second set 70 equals N).

Control circuitry 14 may identify first set 68 and second set 70 using any desired sensing algorithm. In some implementations, non-radio-frequency sensors on UE device 10 (e.g., capacitive proximity sensors, motion sensors, image sensors, light sensors, etc.) may be used to detect when external object 66 overlaps or covers some or all of phased antenna array 50. However, using sensors other than the antennas 30 in phased antenna array 50 can consume an excessive amount of space in UE device 10, can consume an excessive amount of power, and can limit the accuracy with which the control circuitry identifies which antennas need to be disabled to optimize wireless communications in the presence of external object 66.

In implementations that are described herein as an example, transceiver circuitry 26 receives radio-frequency signals using all of the antennas 30 in phased antenna array 50, performs radio-frequency measurements from or on the received radio-frequency signals, and control circuitry 14 identifies first set 68 and second set 70 based on the radio-frequency measurements. The radio-frequency measurements may include measurements of wireless performance metric data. By selecting the first and second sets using radio-frequency signals received by phased antenna array 50 itself, the control circuitry can more precisely and accurately characterize the loading conditions at phased antenna array 50 due to the presence of external object 66 and can more rapidly identify first set 68 and second set 70 relative to implementations where sensors external to phased antenna array 50 are used to detect external object 66.

In the example of FIG. 3, transceiver circuitry 26 may receive radio-frequency signals using each of the N antennas in phased antenna array 50. The radio-frequency signals may, for example, be transmitted by BS 6 at location B. Transceiver circuitry 26 may measure wireless performance metric data from the received radio-frequency signals. Control circuitry 14 may process the wireless performance metric data to identify that antennas 30-1 and 30-2 are being blocked by external object 66 and that antennas 30-3 through 30-N are not being blocked by external object 66. More generally, control circuitry 14 may process the wireless performance metric data to identify that antennas 30-3 through 30-N exhibit superior wireless performance metric data than antennas 30-1 and 30-2 (e.g., consistent with antennas 30-1 and 30-2 being covered by external object 66).

Control circuitry 14 may thereby identify that the first set 68 of antennas in phased antenna array 50 includes antennas 30-1 and 30-2 and that the second set 70 of antennas in phased antenna array 50 includes antennas 30-3 through 30-N. Control circuitry 14 may then disable the antennas 30 in first set 68 and may keep the antennas 30 in second set 70 active during subsequent communications. The antennas 30 in second set 70 may be used to form a UE beam 38B oriented towards location B of BS 6 (e.g., without beamforming contributions from first set 68). UE device 10 may then use the second set 70 of antennas 30 in phased antenna array 50 to convey wireless data with BS 6 over UE beam 38B (e.g., UE beam 38B may form optimal UE beam 30′ of FIG. 2).

Once control circuitry 14 detects that antennas 30-1 and 30-2 are no longer being blocked by external object 66 (or detects that antennas 30-1 and 30-2 otherwise exhibit wireless performance exceeding a threshold), control circuitry 14 may enable antennas 30-1 and 30-2 and all N antennas 30 in phased antenna array 50 may be used to convey wireless data with BS 6 (e.g., using full-array beam 38A). Even though signal beams 38A and 38B are both oriented towards point B, the phase and magnitude controllers 62 of second set 70 may have different phase and magnitude settings when forming UE beam 38B oriented towards point B (e.g., while first set 68 is disabled) than when being used to form the full-array beam 38A oriented towards point B (e.g., because the overall orientation of full-array beam 38A is given by the contribution of the phase and magnitude settings across all N antennas 30 in phased antenna array 50, causing the contribution of the antennas 30 from second set 70 to be different depending on the total number of active antennas 30 in phased antenna array 50).

While maximizing the number of active antennas 30 in phased antenna array 50 may generally serve to maximize the gain of phased antenna array 50, disabling the first set 78 of antennas 30 in phased antenna array 50 may serve to enhance the wireless performance of phased antenna array 50 when external object 66 is present overlapping phased antenna array 50 more than the detriment to peak gain produced by disabling the first set of antennas.

Consider an example in which N=5 and in which external object 66 blocks antennas 30-3 through 30-N. In general, in beamforming, signal adds in the amplitude domain whereas noise adds in the power domain. In this example, if all antennas 30 in phased antenna array 50 were to remain active, each antenna 30 in phased antenna array 50 will receive incident radio-frequency signals with the same amount of noise Nx. However, if the unblocked antennas receive the radio-frequency signals with magnitude M and the blocked antennas receive the radio-frequency signals with magnitude 0.3*M (for example), the overall (combined or added) received signal magnitude output by all N antennas 30 in phased antenna array 50 will be 2.9*M, whereas the overall (combined or added) noise output by phased antenna array 50 will be sqrt(5)*Nx. Transceiver circuitry 26 will thereby gather wireless performance metric data from the received signals such as a sqrt(SNR) value equal to 2.9*M/(sqrt(5)*Nx). This may, for example, correspond to an array SNR gain of 2.26 dB.

On the other hand, if the blocked antennas 30-3 through 30-N are disabled (e.g., as the first set 68 of antennas 30) while unblocked antennas 30-1 and 30-2 are kept active to receive the radio-frequency signals, the overall (combined or added) received signal magnitude output by only antennas 30-1 and 30-2 will be about 2*M, whereas the overall (combined or added) noise output by phased antenna array 50 (i.e., only antennas 30-1 and 30-2) will be sqrt(2)*Nx. Transceiver circuitry 26 will thereby gather wireless performance metric data from the received signals such as a sqrt(SNR) value equal to 2*M/(sqrt(2)*Nx). This may, for example, correspond to an array SNR gain of 3 dB, which is higher than had antennas 30-3 through 30-N been kept active (e.g., 2.26 dB). In this way, disabling the first set 68 of antennas 30 may serve to eliminate all of the noise contributions of the first set of antennas (whereas the signal contributions from the first set of antennas are already relatively low given the blockage by external object 66). This can cause the wireless performance metric data (e.g., SNR) and thus the wireless performance of UE device 10 to be more optimal than had the first set 68 of antennas 30 remained active. In other words, tapering phased antenna array 50 may serve to increase the overall wireless performance of antenna 50 despite any reduction in received signal magnitude due to the presence of external object 66.

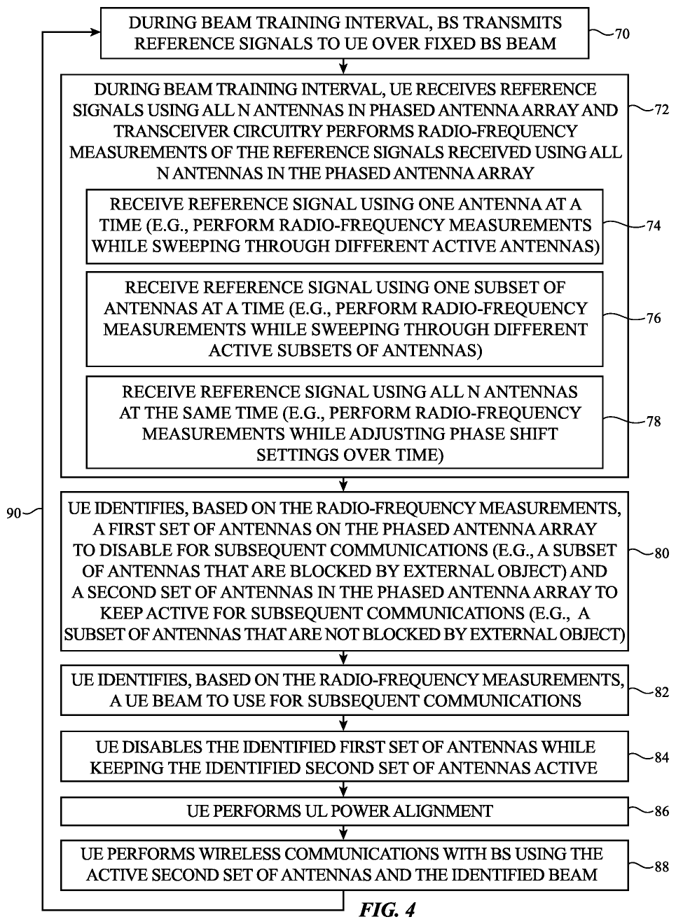

FIG. 4 is a flow chart of illustrative operations that may be performed by BS 6 and UE device 10 to convey wireless data (e.g., using an array tapering scheme at UE device 10). The operations of FIG. 4 may be performed upon initialization, connection, and/or registration of UE device 10 to BS 6, in response to UE device 10 having moved or rotated with respect to BS 6 (e.g., after initialization, connection, and/or registration to BS 6), in response to UE device 10 having disconnected from BS 6, in response to wireless performance metric data less than a threshold being gathered at BS 6 and/or UE device 10, periodically, and/or in response to any desired trigger condition.

At operation 70, BS 6 may transmit reference signals 42 (FIG. 2) to UE device 10 over a fixed BS beam (e.g., BS beam 34 of FIG. 2). BS 6 may, for example, transmit reference signals 42 during a beam training interval (e.g., a protocol-specified period for UE device 10 to measure reference signals 42 for identifying an optimal UE beam to use in communicating with BS 6). Implementations in which UE device 10 performs array tapering based on radio-frequency measurements of reference signals 42 transmitted during the beam training interval are described herein as an example. More generally, UE device 10 may perform the array tapering described herein based on radio-frequency measurements of any downlink or broadcast signals transmitted by BS 6 or any other desired external equipment at any desired time.

At operation 72, UE device 10 may receive reference signals 42 during the beam training interval. Transceiver circuitry 26 may receive reference signals 42 over all N of the antennas 30 in phased antenna array 50. Transceiver circuitry 26 may perform, gather, and/or generate radio-frequency measurements from the received reference signals. For example, transceiver circuitry 26 may generate, measure, gather, calculate, compute, identify, or obtain wireless performance metric data from the received reference signals.

Each of the N antennas 30 in phased antenna array 50 may be active and may receive reference signals 42 at least once during the beam training interval (e.g., during processing of operation 72). If desired, control circuitry 14 (FIG. 1) may activate different antennas 30 in phased antenna array 50 at different times while the other antennas 30 in phased antenna array 50 are disabled (e.g., may sweep over different active antennas 30) during reception of reference signals 42 by phased antenna array 50.

For example, as shown by operation 74, control circuitry 14 may sweep through different single active antennas 30 (and the corresponding signal paths 28) in phased antenna array 50 while receiving reference signals 42 and gathering wireless performance metric data. In the implementation of FIG. 3 and where N=4, control circuitry 14 may activate antenna 30-1 at a first time while antennas 30-2 through 30-N are disabled. Antenna 30-1 may receive reference signals 42 and transceiver circuitry 26 may gather first wireless performance metric data (e.g., a first SNR value) from the reference signals 42 received by antenna 30-1. Control circuitry 14 may then switch the active antenna in phased antenna array 50 by activating antenna 30-2 at a second time while antennas 30-1, 30-3, and 30-N are disabled. Antenna 30-2 may receive reference signals 42 and transceiver circuitry 26 may gather second wireless performance metric data (e.g., a second SNR value) from the reference signals 42 received by antenna 30-2. Control circuitry 14 may then switch the active antenna in phased antenna array 50 by activating antenna 30-3 at a third time while antennas 30-1, 30-2, and 30-N are disabled. Antenna 30-3 may receive reference signals 42 and transceiver circuitry 26 may gather third wireless performance metric data (e.g., a third SNR value) from the reference signals 42 received by antenna 30-3. Control circuitry 14 may then switch the active antenna in phased antenna array 50 by activating antenna 30-4 at a third time while antennas 30-1, 30-2, and 30-3 are disabled. Antenna 30-N may receive reference signals 42 and transceiver circuitry 26 may gather fourth wireless performance metric data (e.g., a fourth SNR value) from the reference signals 42 received by antenna 30-3.

Control circuitry 14 may store the gathered wireless performance metric data for subsequent processing (e.g., for selecting the first set 68 of antennas 30 to disable for subsequent communications). Receiving reference signals 42 and gathering wireless performance metric data sequentially using each of the N antennas 30 in this way may allow control circuitry 14 to gather a complete characterization of the current environmental conditions for antennas 30 (e.g., to determine whether external object 66 is blocking each of antennas 30). However, sequentially activating a single antenna 30 at a time can be excessively time consuming and can exhibit less sensitivity relative to implementations where multiple antennas 30 are concurrently active while receiving reference signals 42.

In another example, as shown by operation 76, control circuitry 14 may sweep through different subsets of one or more active antennas 30 in phased antenna array 50 (and the corresponding signal paths 28) while receiving reference signals 42 and gathering wireless performance metric data. Each subset may include some, all, or only one of the N antennas 30 in phased antenna array 50. For example, in the implementation of FIG. 3 and where N=4, control circuitry 14 may activate antennas 30-1, 30-2, 30-3, and 30-N at a first time. Antennas 30-1, 30-2, 30-3, and 30-N may receive reference signals 42 and transceiver circuitry 26 may gather first wireless performance metric data (e.g., a first SNR value) from the reference signals 42 received by antennas 30-1 through 30-N. Control circuitry 14 may then sweep through different subsets of active antennas in phased antenna array 50 by activating only antennas 30-1, 30-2, and 30-3 at a second time, only antennas 30-1, 30-2, and 30-N at a third time, only antennas 30-2, 30-3, and 30-N at a fourth time, only antennas 30-1, 30-3, and 30-N at a fifth time, only antennas 30-1 and 30-2 at a sixth time, only antennas 30-1 and 30-3 at a seventh time, only antennas 30-1 and 30-N at an eighth time, only antennas 30-2 and 30-N at a ninth time, only antennas 30-3 and 30-N at a tenth time, only antenna 30-1 at an eleventh time, only antenna 30-2 at a twelfth time, only antenna 30-3 at a thirteenth time, and only antenna 30-N at a fourteenth time, etc. The active antenna(s) may receive reference signals 42 and transceiver circuitry 26 may gather wireless performance metric data from the received reference signals at each of these times.

Control circuitry 14 may store the gathered wireless performance metric data for subsequent processing (e.g., for selecting the first set 68 of antennas 30 to disable for subsequent communications). Receiving reference signals 42 and gathering wireless performance metric data sequentially using different subsets of antennas 30 in this way may allow control circuitry 14 to gather a complete characterization of the current environmental conditions for antennas 30 (e.g., to determine whether external object 66 is blocking each subset antennas 30) in a manner that exhibits higher sensitivity than sweeping through single active antennas 30 (e.g., at operation 74). This may, for example, serve to minimize false positives and false negatives in detecting external object 66. However, sequentially activating different subsets of antennas 30 at a time can be excessively time consuming and can face timing and hardware constraints (e.g., due to the stabilization time required after disabling signal paths 28).

In yet another example, as shown by operation 78, control circuitry 14 keep all N antennas 30 in phased antenna array 50 active while receiving and measuring reference signals 42. Rather than switching/sweeping through different active antennas (e.g., as in operations 74 and 76), control circuitry 14 may concurrently keep all N antennas active but may instead sweep over different phase settings over time (e.g., during the beam training interval). In other words, control circuitry 14 may sweep phased antenna array 50 over a set of different UE beams 38 formed by all N antennas 30 (e.g., full array beams 38A of FIG. 3). Transceiver circuitry 26 may gather wireless performance metric data from the received reference signals 42. For example, all N antennas 30 may receive reference signals 42 using first phase and magnitude settings (e.g., a first UE beam at a first beam pointing direction) at a first time, may receive reference signals 42 using second phase and magnitude settings (e.g., a second UE beam at a second beam pointing direction) at a second time, may receive reference signals 42 using third phase and magnitude settings (e.g., a third UE beam at a third beam pointing direction) at a third time, etc.

Control circuitry 14 may store the gathered wireless performance metric data for subsequent processing (e.g., for selecting the first set 68 of antennas 30 to disable for subsequent communications). Receiving reference signals 42 and gathering wireless performance metric data using all N antennas 30 while sweeping over phase and magnitude settings in this way may be faster than sequentially activating (deactivating) one or more of antennas 30, particularly when N becomes relatively large, because control circuitry 14 can adjust phase and magnitude controllers 62 (FIG. 3) much faster than deactivating and activating different antennas 30 and signal paths 28. In addition, determination of the first set 68 of antennas 30 to deactivate for subsequent communications can be integrated into the existing beam training algorithm with which phased antenna array 50 discovers the optimal UE beam (e.g., UE beam 38′ of FIG. 2) to use in communicating with BS 6. In general, UE device 10 may perform one or more of operations 74-78 in receiving and measuring reference signals 42.

At operation 80, control circuitry 14 on UE device 10 may identify (e.g., detect, select, compute, calculate, output, etc.), based on the radio-frequency measurements (e.g., wireless performance metric data) gathered by transceiver circuitry 26 during the beam training interval (e.g., while processing operation 72), the first set 68 of antennas 30 in phased antenna array 50 (FIG. 3) to disable and the second set 70 of antennas 30 in phased antenna array 50 to keep active during subsequent communications. Put differently, control circuitry 14 may identify (e.g., detect, select, compute, calculate, output, etc.), based on the radio-frequency measurements (e.g., wireless performance metric data) gathered by transceiver circuitry 26 during the beam training interval, any antennas 30 in phased antenna array 50 that are being blocked by external object 66 (or that otherwise exhibit insufficient wireless performance under the current environmental loading conditions) and the antennas 30 in phased antenna array 50 that are not being blocked by external object 66 (or that otherwise exhibit sufficient wireless performance under the current environmental loading conditions). The antennas 30 being identified as being blocked may form first set 68 whereas the antennas 30 that are identified as not being blocked may form second set 70. In the example of FIG. 3, control circuitry 14 may identify first set 68 as including antennas 30-1 and 30-2 and may identify second set 70 as including antennas 30-3 through 30-N.

At operation 82, control circuitry 14 may identify (e.g., detect, calculate, etc.) the optimal UE beam (e.g., optimal UE beam 38′) of phased antenna array 50 for use in subsequent communications with BS 6. The optimal UE beam may be a UE beam of only the second set 70 of antennas 30 (e.g., UE beam 38B of FIG. 3) when there is at least one antenna 30 in first set 68. Control circuitry 14 may identify the optimal UE beam in a separate processing operation than the processing operations used to identify sets 68 and 70 (e.g., may sweep the antennas 30 in second set 70 over different UE beams 38B of FIG. 3 while receiving and measuring reference signals until the UE beam exhibiting optimal wireless performance is detected). Alternatively, control circuitry 14 may identify the optimal UE beam in the same processing operation(s) used to identify sets 68 and 70 (e.g., when operation 78 is performed while processing operation 72).

At operation 84, control circuitry 14 may disable, deactivate, mute, power off, power down, or otherwise de-couple the antennas 30 in first set 68 and/or the corresponding signal paths 28 from transceiver circuitry 26. Put differently, control circuitry 14 may place the antennas 30 in first set 68 (e.g., the blocked antennas 30 of phased antenna array 50) and/or the corresponding signal paths 28 in a disabled, deactivated, muted, powered off, powered down state. Control circuitry may concurrently enable, activate, unmute, power on, power up, or otherwise couple the antennas 30 in second set 70 and/or the corresponding signal paths 28 to transceiver circuitry 26. Put differently, control circuitry 14 may place the antennas 30 in second set 70 (e.g., the unblocked antennas 30 of phased antenna array 50) and/or the corresponding signal paths 28 in an enabled, activated, active, unmuted, powered on, or powered up state.

At operation 86, UE device 10 may perform an uplink power alignment procedure if desired. This may involve, for example, adjusting the transmit power level(s) of the antenna(s) 30 in second set 70 (e.g., the corresponding power amplifier(s) 58) that have remained active in a manner that configures the antennas in second set 70 to exhibit a normalized level of transmit power (e.g., based on the number of antennas 30 in second set 70). Each antenna 30 in second set 70 may be configured to exhibit a lower transmit power level when second set 70 is relatively large than when second set 70 is relatively small, for example. This may, for example, allow UE device 10 to maintain a consistent overall transmit power level regardless of the number of antennas 30 in second set 70.

At operation 88, UE device 10 may perform subsequent wireless communications (e.g., may convey wireless data using wireless signals 32 of FIG. 1) with BS 6 using the active antennas 30 from second set 70 (and the corresponding signal paths 28), while the antennas 30 in first set 68 (and the corresponding signal paths 28) are disabled. The second set 70 of antennas 30 may, for example, form the optimal UE beam (e.g., optimal UE beam 38′ of FIG. 2 or UE beam 38B of FIG. 3) and may convey wireless data with BS 6 over the optimal UE beam. In the example of FIG. 3, for instance, second set 70 may form UE beam 38B and may convey wireless signals over UE beam 38B while antennas 30-1 and 30-2 are disabled and do not participate in the formation of UE beam 38B (e.g., antennas 30-1 and 30-2 and the corresponding signal paths 28 do not convey wireless data or radio-frequency signals while the antennas 30 in second set 70 convey wireless data). Processing may then loop back to operation 90 to update the active antenna(s) and/or optimal UE beam over time as needed to continue to optimize wireless performance of UE device 10 under different environmental conditions (e.g., as external object 66 enters or leaves the vicinity of phased antenna array 50, as external object 66 moves relative to phased antenna array 50, as UE device 10 moves or rotates relative to BS 6, etc.).

The operations performed by control circuitry 14 to identify the first set 68 and second set 70 of antennas 30 in phased antenna array 50 (e.g., at operation 80 of FIG. 4) may depend on the technique with which antennas 30 were used to measure reference signals 42 (e.g., may depend on whether operation 74, 76, or 78 was performed while processing operation 72). FIG. 5 is a flow chart of operations that may be performed by control circuitry 14 (e.g., while processing operation 80 of FIG. 4) when the reference signals were measured while UE device 10 swept over different single active antennas 30 in phased antenna array 50 (e.g., in implementations where control circuitry 14 performed operation 74 while processing operation 72 of FIG. 4).

At operation 92, control circuitry 14 may identify the wireless performance metric data gathered from reference signals 42 received by each antenna 30 (e.g., while that antenna was the only active antenna receiving reference signals 42).

At operation 94, control circuitry 14 may select or identify, as the first set 68 of antennas 30 to be disabled for subsequent communications, one or more of the antennas 30 in phased antenna array 50 that produced wireless performance metric data less than a threshold level or outside of a desired range of values (e.g., SNR values less than a threshold SNR value). Alternatively, control circuitry 14 may select or identify, as the first set 68 of antennas 30 to be disabled for subsequent communications, one or more of the antennas 30 in phased antenna array 50 that produced wireless performance metric data that differs from the wireless performance metric data gathered by the other antennas 30 in phased antenna array 50 by more than a threshold amount. Control circuitry 14 may select or identify, as the second set 70 of antennas 30 to keep active for subsequent communications, the remaining antennas 30 of phased antenna array 50 (e.g., the antenna panel) that are not a part of first set 68.

In the example of FIG. 3, for instance, the control circuitry may identify that the first wireless performance metric data (e.g., the first SNR value) gathered while only antenna 30-1 was active and that the second wireless performance metric data (e.g., the second SNR value) gathered while only antenna 30-2 was active lies outside a desired range of values (e.g., are less than an SNR threshold level), or that the first and second wireless performance metric data differs from the wireless performance metric data gathered by antennas 30-3 through 30-N by more than a threshold amount (e.g., due to antennas 30-1 and 30-2 being covered by external object 66). Control circuitry 14 may then select or set antennas 30-1 and 30-2 as the first set 68 of antennas 30 and may disable antennas 30-1 and 30-2 (e.g., at operation 84 of FIG. 4) for subsequent communications. Conversely, control circuitry 14 may select or set antennas 30-3 through 30-N as the second set 70 of antennas 30 and may keep antennas 30-3 through 30-N active for subsequent communications.

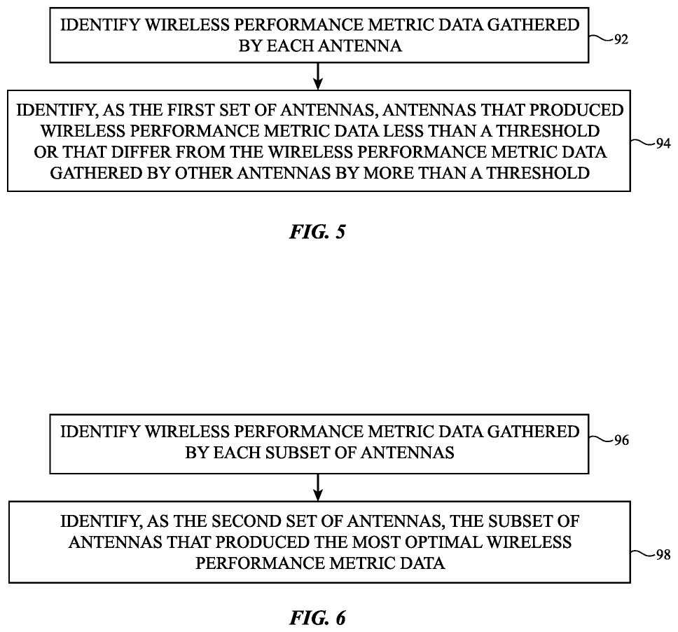

FIG. 6 is a flow chart of operations that may be performed by control circuitry 14 (e.g., while processing operation 80 of FIG. 4) when the reference signals were measured while UE device 10 swept over different subsets of active antennas 30 in phased antenna array 50 (e.g., in implementations where control circuitry 14 performed operation 76 while processing operation 72 of FIG. 4).

At operation 96, control circuitry 14 may identify the wireless performance metric data gathered from reference signals 42 received by each subset of antennas 30 (e.g., while the antenna(s) from that subset was/were the only active antenna(s) receiving reference signals 42).

At operation 98, control circuitry 14 may select or identify, as the second set 70 of antennas 30 to keep enabled for subsequent communications, the subset of antennas 30 that produced the most optimal wireless performance metric data (e.g., the highest combined SNR value) while receiving reference signals 42. If the subset includes all of the N antennas 30 in phased antenna array 50, first set 68 may have zero elements and control circuitry 14 may keep all N antennas 30 in phased antenna array 50 active during subsequent communications (As second set 70). On the other hand, if the subset includes fewer than the N antennas 30 in phased antenna array 50, first set 68 may have at least one element and control circuitry 30 may disable the antennas not included in the subset (e.g., the antennas in first set 68 and not included in second set 70) for subsequent communications (e.g., while processing operation 84 of FIG. 4).

In the example of FIG. 3, for instance, the control circuitry may identify that the first wireless performance metric data (e.g., the first SNR value) gathered while only antennas 30-3 through 30-N were active produced more optimal wireless performance metric data (e.g., the highest SNR) from all of the different subsets and combinations of active antennas that received reference signals 42 while processing operation 76 of FIG. 4 (e.g., due to antennas 30-3 through 30-N being uncovered by external object 66). Control circuitry 14 may then select or set antennas 30-3 through 30-N as the second set 70 of antennas 30 and may keep antennas 30-3 through 30-N active for subsequent communications. At the same time, control circuitry 14 may select or set antennas 30-1 and 30-2 as the first set 68 of antennas 30 and may disable antennas 30-1 and 30-2 for subsequent communications.

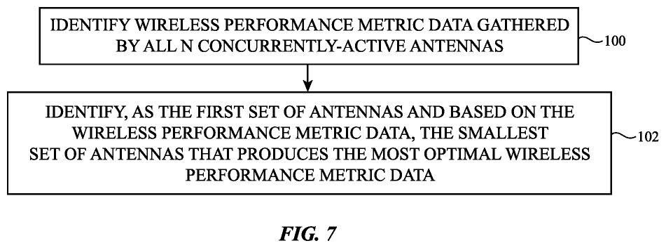

FIG. 7 is a flow chart of operations that may be performed by control circuitry 14 (e.g., while processing operation 80 of FIG. 4) when the reference signals were measured while UE device 10 kept all N antennas 30 in phased antenna array 50 active but instead swept over different phase settings (e.g., in implementations where control circuitry 14 performed operation 78 while processing operation 72 of FIG. 4).

At operation 100, control circuitry 14 may identify the wireless performance metric data gathered from reference signals 42 received by all N antennas 30 under different phase settings. This may include, for example, channel estimates h gathered using each of the N antennas 30 in phased antenna array 50.

At operation 102, control circuitry 14 may select or identify, as the first set 68 of antennas 30 to disable for subsequent communications, the smallest number of antennas 30 that would produce the most optimal wireless performance metric data were those antennas to be disabled for subsequent communications. The remaining antennas 30 may form second set 70. Alternatively, control circuitry 14 may select, as the second set 70 of antennas 30, the antennas that produced the most optimal wireless performance metric data (e.g., the highest SNR) after combining channel estimates h derived from reference signals 42, assuming noise is white additive Gaussian noise.

Control circuitry 14 may, for example, input the wireless performance metric data to a mathematical optimization function or algorithm. Control circuitry 14 may identify, based on the mathematical optimization function or algorithm, which antennas 30 in phased antenna array 50 are negatively contributing to the overall wireless performance (e.g., SNR) of phased antenna array 50 and may select those antennas to disable for subsequent communications (as first set 68).

Consider one simplified example of such a mathematical optimization function or algorithm. In this example, transceiver circuitry 26 may generate, from the reference signals 42 received by antennas 30, a spatial channel covariance matrix Rₕ (e.g., the spatial covariance matrix of the channel at the analog antenna array). Channel covariance matrix Rₕ may, for example, be an N-by-N matrix having complex elements having rank 1, each representing the channel coefficient of a respective one of the antennas 30. The power of a given signal beam w of phased antenna array 50 is given by the equation ρ(w)=w^{H}Rₕw, where ∥w∥₂=1. The eigenvector of channel covariance matrix Rₕ having the largest eigenvector can be denoted as uₕ, where ∥uₕ∥₂=1. In this case, ρ(uₕ)≥ρ(w) for all w having N complex elements and where ∥w∥₂=1. Thus eigenvector uₕ represents the optimal continuous UE beam for phased antenna array 50 (e.g., where the UE beam is represented by a complex four-dimensional vector normalized to 1). In the case of a single ray channel, uₕ is the channel vector at the analog array: Rₕ=uₕuₕ^{H}, where ρ(w)=w^{H}uₕuₕ^{H}W=|w^{H}uₕ|₂. For a multi-ray channel, the optimal solution can be approximated assuming a single ray channel corresponding to eigenvector uₕ.

The optimal UE beam (e.g., eigenvector uₕ) may be formed through the corresponding setting of phase and magnitude controllers 62 across the N antenna 30 in phased antenna array 50. However, one or more of the N antennas 30 may be disabled (e.g., as first set 68) when control circuitry 14 hard tapers phased antenna array 50. This may be conceptually equivalent to identifying a subarray of phased antenna array 50 (e.g., a subarray to remain active as second set 70) followed by a phase computation (e.g., for forming UE beam 38B of FIG. 3). In practice, hard tapering may improve wireless performance more than simply setting desired phase shifts across all N antennas 30 in phased antenna array 50 and/or may serve to minimize power consumption in UE device 10.

To determine whether hard tapering will improve wireless performance more than only phase shifting, eigenvector uₕ may be rewritten as uₕ=[a₀*exp(j*+ϕ₀); . . . ; a_{N-1}*exp(j*+ϕ_{N-1})], where a₀, . . . , a_{N-1} represent the channel coefficient amplitudes and ϕ₀, . . . , ϕ_{N-1} represent the channel coefficient phases for each of the N antennas 30 in phased antenna array 50 (e.g., as measured by transceiver circuitry 26 from reference signals 42 while processing operation 78 of FIG. 4). It can be assumed without loss of generality that a₀≤ . . . ≤a_{N-1}. While processing operation 80 of FIG. 4, control circuitry 14 may identify (e.g., determine, compute, detect, select, etc.) the set K⊆{0, . . . , N−1} of antennas 30 to keep activated for signal beamforming and for conveying wireless data (e.g., where set K forms the second set 70 of antennas 30 in phased antenna array 50). Set K may sometimes also be referred to herein as the subarray of phased antenna array 50 to keep active. For set K, any desired algorithm may be used for phase quantization and beam forming (e.g., a rotating electrical vector (REV) algorithm, etc.). However, control circuitry 14 may separate the identification of set K (e.g., second set 70) from the succeeding phase shift computation (e.g., for forming UE beam 38B using the antennas 30 in set K) with only minor performance loss.

Control circuitry 14 may identify set K (e.g., second set 70) using the following algorithm, as one example. Control circuitry 14 may first sort channel coefficients, such that it can be assumed that 0<a₀≤ . . . ≤a_{N-1}. If Aₙ is defined by Aₙ=aₙ+ . . . +a_{N-1}, where n∈{0, . . . , N−1}, control circuitry 14 may define a decision threshold τₙ by τₙ:=Aₙ(sqrt(N+1−n)/(sqrt(N−n)−1)), where control circuitry 14 may compute sqrt(N+1−n)/(sqrt(N−n)−1) in advance and store in a table for later use. Threshold τ_{N} may be equal to zero (e.g., in the case where just a single antenna 30 is active). For a number of antennas 30 to be deactivated from hypothesis n=1 to hypothesis n=N, if aₙ₋₁>τₙ, then control circuitry 14 may select set K to be given by K:={n−1, . . . , N−1} and the algorithm may terminate (e.g., when the channel coefficient exceeds the threshold, all processed antennas 30 up to that point in the algorithm can be deactivated). Control circuitry 14 may undo the sorting of channel coefficients for the antennas to be activated (e.g., the antennas in set K). Control circuitry 14 may perform beamforming by identifying the phase settings for the antennas 30 in set K that form the optimal signal beam 38B for the antennas 30 in set K (e.g., while processing operation 82 of FIG. 4). As an example, control circuitry 14 may input set K to a phase quantization algorithm (e.g., where the antennas 30 in set K form the array over which beamforming is performed but represent only a subset of the antennas 30 in phased antenna array 50).

Consider a more specific example in which there are N=4 antennas 30 in phased antenna array 50 that are all kept concurrently active while measuring reference signal 42. In this case, the reference signal as received by each antenna 30 in phased antenna array 50 may have a magnitude M (e.g., the first antenna may receive the reference signal with magnitude M1, the second antenna may receive the reference signal with magnitude M2, the third antenna may receive the reference signal with magnitude M3, and the fourth antenna may receive the reference signal with magnitude M4). Each antenna may receive the reference signal with a uniform amount of noise Nx. Transceiver circuitry 26 may, for example, measure each magnitude M while phased antenna array 50 receives the reference signals.

If the low noise amplifier(s) 60 coupled to each antenna 30 imparts a gain G to the received signals, the signals are received at a signal combiner in transceiver circuitry 26 with magnitude M1*G from the first antenna 30, magnitude M2*G from the second antenna 30, M3*G from the third antenna 30-3, and magnitude M4*G from the fourth antenna 30. Similarly, noise Nx is multiplied by G from each antenna 30. Control circuitry 14 may then determine whether to disable a given one of the antennas 30 and its corresponding signal path 28 (e.g., as the first set 68 of antennas 30). The signal combiner may combine the signal magnitude and noise received from each antenna 30.

Under the assumption that M˜RSRP (or RSSI)˜SNR, signal combiner in transceiver circuitry 26 may output a combined (added) signal having an SNR given by the expression 2*G*log₁₀[(M1+M2+M3+M4)/sqrt(4Nx²)]. Assuming that S1≥S2≥S3≥S4 and that S2=S1*x, S3=S1*y, and S4=S1*z (e.g., where x, y, and z are constants), control circuitry 14 may select the fourth antenna 30 to form first set 68 and may disable the fourth antenna 30 for subsequent communications when SNR_{1,2,3}≥SNR_{1,2,3,4} (e.g., when the SNR produced by only the first through third antennas is greater than or equal to the SNR produced by all four antennas). Combining this condition with the expression for SNR above and simplifying, control circuitry 14 may select the fourth antenna 30 to form first set 68 and may disable the fourth antenna 30 for subsequent communications when the condition (sqrt(4/3)−1)*(1+x+y)≥z is satisfied. Plugging an example where x=y=1 and z=−6.83 dB into this condition simplifies to 0.464≥0.456. Since this condition is true, the condition SNR_{1,2,3}≥SNR_{1,2,3,4} is true and phased antenna array 50 would exhibit greater wireless performance with the fourth antenna disabled than with the fourth antenna enabled. As such, control circuitry 14 may identify first set 68 as including the fourth antenna, may identify second set 70 as including the first through third antennas, and may disable the fourth antenna for subsequent communications.

To further illustrate why this algorithm succeeds, first define a beam weight vector wₙ:=[0; . . . ; 0; exp(j*ϕₙ); . . . ; exp(j*ϕ_{N-1})]/sqrt(N−n), where n∈{0, . . . , N−1} represents the deactivated antennas and N−n represents the active antennas. Active antennas can assume ideal continuous phase shifts ϕ₀, . . . , ϕ_{N-1}∈(−π,π]. In the example where no antennas are deactivated, n=0 and the beam weight vector is given by w₀=[exp(j*ϕ_{N}); . . . ; exp(j*ϕ_{N-1})]/sqrt(N). For examples where n∈{1, . . . , N−1}, there are two received root power hypotheses for n versus n−1 deactivated antenna elements, wₙ^{H}h=Aₙ/sqrt(N−n) and wₙ₋₁^{H}h=(aₙ₋₁+Aₙ)/sqrt(N+1−n). Hypothesis n−1 wins over hypothesis n if and only if Aₙ/sqrt(N−n)<(aₙ₋₁+Aₙ)/sqrt(N+1−n) and if and only if aₙ₋₁>τₙ. put differently, control circuitry 14 may process hypothesis whereby different antennas 30 are deactivated until the control circuitry determines that the array would perform worse. These examples assume optimum continuous phases in the algorithm, as practical quantized phases are determined after subarray selection (e.g., after identifying second set 70). That is, control circuitry 14 may bias subarray selection in the direction of less aggressive antenna deactivation.

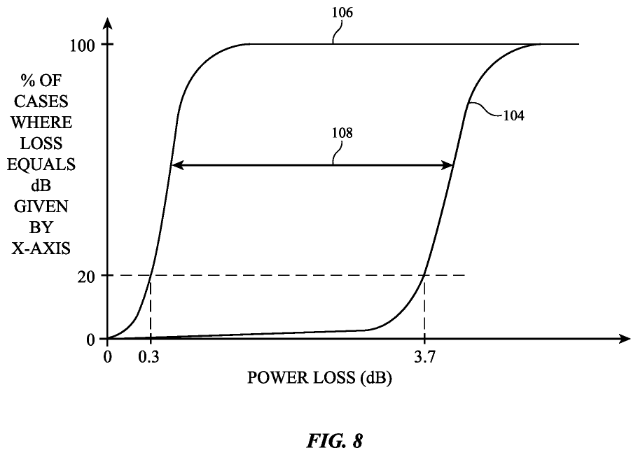

FIG. 8 is a plot showing how performing array tapering in communicating with a wireless base station may optimize wireless performance for UE device 10. FIG. 8 plots a cumulative distribution function (CDF) of power loss (e.g., where the vertical axis plots the percent of cases where loss equals the power loss in dB given by the corresponding point along the X-axis). Curve 104 plots the CDF of UE device 10 without performing array tapering (e.g., in which all N antennas 30 in phased antenna array 50 remain active despite the presence of external object 66). Curve 106 plots the CDF of UE device 10 with array tapering (e.g., in which one or more of the antennas 30 in phased antenna array 50 are disabled). As shown by curves 106 and 104, array tapering may improve performance by a substantial margin 108. For example, without array tapering, 20% of cases may involve a power loss of 3.7 dB, whereas 20% of cases may involve a power loss of only 0.3 dB when performing array tapering. The example of FIG. 8 is illustrative and non-limiting. Curves 106 and 104 may have other shapes in practice.

When phased antenna array 50 is used to receive radio-frequency signals, the thresholds may be selected to maximize performance. When phased antenna array 50 is used to transmit radio-frequency signals, using all N antenna elements to transmit radio-frequency signals generally always results in higher effective isotropic radiated power (EIRP). If desired, control circuitry 14 may bias antenna switching (e.g., disabling or enabling) using a bias threshold τ_{bias}>0. For n∈{1, . . . , N−1}, control circuitry 14 may use biased threshold τₙ:=Aₙ*[(sqrt(N+1−n)/(τ_{bias}*sqrt(N−n)))−1]. When τ_{bias}<1, control circuitry 14 may disable antennas 30 more aggressively. This can produce increased power savings but may reduce both transmit and receive performance. When τ_{bias}=1, control circuitry 14 may perform its baseline algorithm, maximizing receiver performance. When τ_{bias}>1, control circuitry 14 may switch off antennas 30 less aggressively. This may reduce receive performance but can increase transmit performance. If desired, control circuitry 14 may introduce different thresholds τ_{bias,RX} and τ_{bias,TX} for individual transmit/receive control.

In implementations where phased antenna array 50 supports multiple polarizations (e.g., vertical (V) and horizontal (H) polarizations), the same antennas 30 may be turned on or off during communications regardless of polarization. Alternatively, control circuitry 14 may determine the antennas 30 to include in set 68 to disable for only the stronger polarization and may then disable those antennas for both polarizations. Alternatively, control circuitry 14 may separately process both polarizations to disable different sets of antennas depending on polarization.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

UE device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The methods and operations described above in connection with FIGS. 1-15 may be performed by the components of UE device 10 and/or BS 6 using software, firmware, and/or hardware (e.g., dedicated circuitry or hardware). Software code for performing these operations may be stored on non-transitory computer readable storage media (e.g., tangible computer readable storage media) stored on one or more of the components of UE device 10 and/or BS 6. The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of UE device 10 and/or BS 6. The processing circuitry may include microprocessors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. A method of operating an electronic device having antennas arranged in a phased antenna array, the method comprising:
receiving, using the phased antenna array, radio-frequency signals transmitted by an external device;
measuring, using transceiver circuitry communicably coupled to the phased antenna array, wireless performance metric data from the radio-frequency signals received by the phased antenna array;
disabling, using one or more processors, a first set of antennas in the phased antenna array, the antennas in the first set being selected based on the wireless performance metric data; and
conveying, using a second set of antennas in the phased antenna array, wireless data while the first set of antennas is disabled.

2. The method of claim 1, wherein the external device is a wireless base station and conveying the wireless data comprises conveying the wireless data with the wireless base station.

3. The method of claim 2, wherein receiving the radio-frequency signals comprises receiving a reference signal transmitted by the wireless base station.

4. The method of claim 3, wherein receiving the reference signal comprises receiving the reference signal during a beam training interval.

5. The method of claim 1, wherein receiving the radio-frequency signals comprises receiving the radio-frequency signals using each antenna in the phased antenna array.

6. The method of claim 5, wherein receiving the radio-frequency signals using each antenna in the phased antenna array comprises:
activating a single antenna in the phased antenna array while a remainder of the antennas in the phased antenna array are disabled; and
changing, over time, the single antenna in the phased antenna array that is active while the phased antenna array receives the radio-frequency antennas.

7. The method of claim 5, wherein receiving the radio-frequency signals using each antenna in the phased antenna array comprises:
activating a plurality of antennas in the phased antenna array while a remainder of the antennas in the phased antenna array are disabled; and
changing, over time, the plurality of antennas in the phased antenna array that is active while the phased antenna array receives the radio-frequency antennas.

8. The method of claim 5, wherein receiving the radio-frequency signals using each antenna in the phased antenna array comprises:
concurrently activating each antenna in the phased antenna array; and
changing phase settings of the antennas in the phased antenna array while the phased antenna array receives the radio-frequency antennas.

9. The method of claim 1, wherein the first set of antennas includes only one antenna in the phased antenna array.

10. The method of claim 1, wherein the first set of antennas includes a plurality of antennas in the phased antenna array.

11. The method of claim 1, further comprising:
normalizing, using the one or more processors, transmit power levels of the second set of antennas based on a number of antennas in the second set of antennas.

12. An electronic device comprising:
antennas arranged in a phased antenna array, the phased antenna array being configured to receive a reference signal transmitted by an external device;
signal paths coupled to the antennas in the phased antenna array;
transceiver circuitry communicably coupled to the antennas in the phased antenna array over the signal paths; and
one or more processors configured to deactivate a first subset of the signal paths based on the reference signal received by the phased antenna array, the transceiver circuitry being configured to transmit wireless data to the phased antenna array over a second subset of the signal paths while the first subset of the signal paths is deactivated.

13. The electronic device of claim 12, wherein the phased antenna array includes a first set of antennas coupled to the first subset of the signal paths and a second set of antennas coupled to the second subset of the signal paths, the electronic device further comprising:
phase and magnitude controllers disposed on the second subset of the signal paths and configured to form, using the second set of antennas, a signal beam, the one or more processors being configured to steer the signal beam over a plurality of beam pointing directions.

14. The electronic device of claim 12, wherein the phased antenna array includes a first antenna, a second antenna, and a third antenna, the phased antenna array being configured to
receive, at a first time, the reference signal using the first antenna while the second antenna and the third antenna are inactive;
receive, at a second time, the reference signal using the second antenna while the first antenna and the third antenna are inactive; and
receive, at a third time, the reference signal using the third antenna while the first antenna and the second antenna are inactive.

15. The electronic device of claim 12, wherein the phased antenna array includes a first antenna, a second antenna, and a third antenna, the phased antenna array being configured to
receive, at a first time, the reference signal using the first antenna and the second antenna while the third antenna is inactive;
receive, at a second time, the reference signal using the second antenna and the third antenna while the first antenna is inactive; and
receive, at a third time, the reference signal using the first antenna and the third antenna while the second antenna is inactive.

16. The electronic device of claim 12, wherein the phased antenna array is configured to concurrently receive the reference signal using each antenna in the phased antenna array, the electronic device further comprising:
phase and magnitude controllers disposed on the signal paths, the one or more processors being configured to adjust phase settings of the phase and magnitude controllers while the phased antenna array receives the reference signal.

17. The electronic device of claim 12, wherein the phased antenna array includes a first set of antennas coupled to the first subset of the signal paths and a second set of antennas coupled to the second subset of the signal paths, the electronic device further comprising:
an antenna panel having a substrate, the first set of antennas and the second set of antennas being disposed on the substrate, the transceiver circuitry being configured to generate wireless performance metric data based on the reference signal as received by the first set of antennas and the second set of antennas, and the one or more processors being configured to deactivate the first subset of the signal paths based on the wireless performance metric data.

18. A method of operating a user equipment (UE) device to communicate with a wireless base station, the method comprising:
receiving, using a phased antenna array, a reference signal transmitted by the wireless base station;
measuring, using transceiver circuitry, wireless performance metric data from the reference signal received by the phased antenna array;
detecting, using one or more processors and based on the wireless performance metric data, a first set of antennas in the phased antenna array that are at least partially overlapping an external object; and
conveying, using a second set of antennas in the phased antenna array that is different from the first set of antennas, wireless data while the first set of antennas is inactive.

19. The method of claim 18, further comprising:
forming, using the second set of antennas but not the first set of antennas, a signal beam oriented in a beam pointing direction; and
adjusting, using the one or more processors, the beam pointing direction.

20. The method of claim 18, wherein receiving the reference signal comprises:
disabling different subsets of antennas in the phased antenna array at different times while the phased antenna array receives the reference signal.
